(19) United States
(12) Patent Application Publication
(10) Pub. No.: US 2026/0096355 A1
(43) Pub. Date: Apr. 2, 2026

(54) FREQUENCY TUNABLE DEVICE USING MAGNETIC FIELD AND SUPERCONDUCTING DEVICE INCLUDING SAME

(71) Applicant: Samsung Electronics Co., Ltd., Suwon-si (KR)

(72) Inventors: Dae Yun KIM, Suwon-si (KR); In Su JEON, Suwon-si (KR); Hyeok Shin KWON, Suwon-si (KR); Kyung Mee SONG, Suwon-si (KR)

(73) Assignee: Samsung Electronics Co., Ltd., Suwon-si (KR)

(21) Appl. No.: 18/601,993

(22) Filed: Mar. 11, 2024

(30) Foreign Application Priority Data
Sep. 14, 2023 (KR) 10-2023-0122711
Nov. 21, 2023 (KR) 10-2023-0162466

(51) Int. Cl. H10N 69/00; H10N 60/12; H10N 60/82

(52) U.S. Cl. CPC H10N 69/00; H10N 60/12; H10N 60/82

(57) ABSTRACT

Provided are a frequency-tunable device using a magnetic field of a ferromagnetic material, and a superconducting device including the same. The superconducting device according to an embodiment may include: a frequency-tunable device including a Josephson, a first conductive pad and a second conductive pad connected with the first conductive pad by the Josephson junction; a structure including a ferromagnetic material; and a control circuit configured to control a resonant frequency of the frequency-tunable device by applying voltage to the structure to change the saturation magnetization of the ferromagnetic material.

### CROSS-REFERENCE TO RELATED APPLICATIONS

This application claims the benefit under 35 USC § 119(a) of Korean Patent Application No. 10-2023-0122711, filed on Sep. 14, 2023, and No. 10-2023-0162466, filed on Nov. 21, 2023, in the Korean Intellectual Property Office, the entire disclosure of which is incorporated herein by reference for all purposes.

### BACKGROUND

### 1. Field

The following description relates to a frequency-tunable device using the magnetic field of a ferromagnetic material and a superconducting device including the same.

### 2. Description of Related Art

Quantum computers depend on or use quantum mechanical phenomena, such as quantum superposition and quantum entanglement, as operating principles to perform data processing. A unit capable of storing information using a quantum mechanical principle, or the information itself, is called a “quantum bit” or “qubit”, which can be used as a basic unit of information in a quantum computer.

With the growing interest in quantum computers, research on various types of qubits has been progressing. Qubits may be implemented in various ways, such as photon qubits, ion trap qubits, topological qubits, and superconducting qubits. Among these, superconducting qubits using superconducting materials have garnered the most attention to date.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

In one general aspect, a superconducting device includes: a frequency-tunable device including a Josephson, a first conductive pad and a second conductive pad connected with the first conductive pad by the Josephson junction; a structure including a ferromagnetic material; and a control circuit configured to control a resonant frequency of the frequency-tunable device by applying voltage to the structure to change the saturation magnetization of the ferromagnetic material.

The frequency-tunable device may include a tunable qubit or a tunable qubit coupler.

The structure may be configured so that the voltage flows through the structure in a direction perpendicular to a plane of the superconducting device.

The control circuit may be configured to change the saturation magnetization to control the resonant frequency according to a relationship between the saturation magnetization and a magnetic flux passing through the frequency-tunable device, and according to a relationship between the magnetic flux and the resonant frequency.

The structure may further includes an insulator and a heavy metal.

The frequency-tunable device may include the tunable qubit, the tunable qubit may include two Josephson junctions, and one of the Josephson junctions may be between the other Josephson junction and the structure.

The structure may have a flat shape and the ferromagnetic material may have a direction of magnetic anisotropy that is perpendicular to flat shape.

The ferromagnetic material may include gadolinium cobalt (GdCo).

The structure may have a width that is less than 90 micrometers (μm).

The first conductive pad and the second conductive pad may be formed of a superconducting material.

The superconducting material may include aluminum (Al), niobium (Nb), indium (In), alpha-tantalum (α-Ta), titanium (Ti), lead (Pb), vanadium (V), or compounds thereof.

The frequency-tunable device may be a gatemon type.

The structure and the frequency-tunable device may be formed in a stacked structure from bottom to top.

In another general aspect, there is a method of controlling a resonant frequency of a frequency-tunable device through a superconducting device, the superconducting device including the frequency-tunable device, the frequency-tunable device including a first conductive pad, a second conductive pad, a Josephson junction connecting the first conductive pad to the second conductive pad, and a structure which includes a ferromagnetic material, the method includes: applying voltage to the structure; the application of the voltage causing a change to the saturation magnetization of the ferromagnetic material, the ferromagnetic material providing a magnetic field; the change of the saturation magnetization of the ferromagnetic material changing a magnetic flux of the magnetic field where it passes through the frequency-tunable device; and the changing of the magnetic flux changing the resonant frequency of the frequency-tunable device.

The frequency-tunable device may include a tunable qubit or a tunable qubit coupler.

The voltage may move through the structure in a direction perpendicular to a planar dimension of the structure.

The resonant frequency is changed according to a relationship between the saturation magnetization and the magnetic flux and according to a relationship between the magnetic flux and the resonant frequency.

The structure further may include an insulator and a heavy metal, the frequency-tunable device may include two Josephson junctions, and the structure may be positioned outside of a space between the two Josephson junctions.

The frequency-tunable device may be of a transmon type.

In another general aspect, there is a method of changing a resonant frequency of a superconducting quantum interface device (SQUID) device comprising a Josephson junction and a ferromagnetic structure arranged near the SQUID device, and the method includes: emitting, from the ferromagnetic structure, a magnetic field that passes through an area of the SQUID; changing the resonant frequency of the SQUID device by applying a voltage to the superconductive ferromagnetic structure to change the saturation magnetization of the ferromagnetic structure to change the magnetic flux of the magnetic field passing through the area of the SQUID device.

Other features and aspects will be apparent from the following detailed description, the drawings, and the claims.

### BRIEF DESCRIPTION OF THE DRAWINGS

FIG. 1A illustrates a quantum computer chip, according to one or more embodiments.

FIG. 1B is a circuit diagram of a frequency-fixed device according to one or more embodiments.

FIG. 1C is a circuit diagram of a frequency-tunable device, according to one or more embodiments.

FIG. 1D is a circuit diagram for describing resonant frequency control of a tunable qubit, according to one or more embodiments.

FIG. 2 illustrates a superconducting device including a tunable qubit, according one or more embodiments.

FIG. 3 illustrates layers of a superconducting structure, according to one or more embodiments.

FIGS. 4A to 5B are circuit diagrams of magnetic field radiation and the change in a magnetic flux of a magnetic field passing through a tunable qubit according to the application of voltage, according to one or more embodiments.

FIG. 6 shows the relationship between the saturation magnetization of a ferromagnetic material and the magnetic flux passing through a tunable qubit, according to one or more embodiments.

FIG. 7 shows the relationship between magnetic flux and resonant frequency, according to one or more embodiments.

FIGS. 8A to 8C illustrate a process of manufacturing a superconducting device, according to one or more embodiments.

FIG. 9 illustrates a method for controlling a resonant frequency of a tunable qubit, according to one or more embodiments.

Throughout the drawings and the detailed description, unless otherwise described, the same or like drawing reference numerals will be understood to refer to the same or like elements, features, and structures. The relative size, the proportion, and the depiction of these elements may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

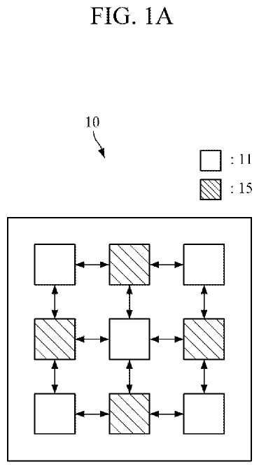

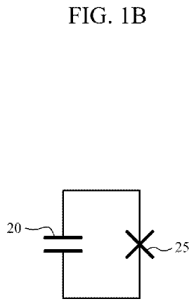

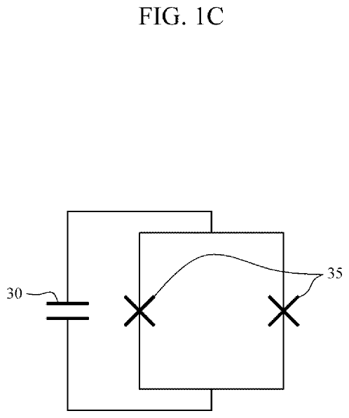

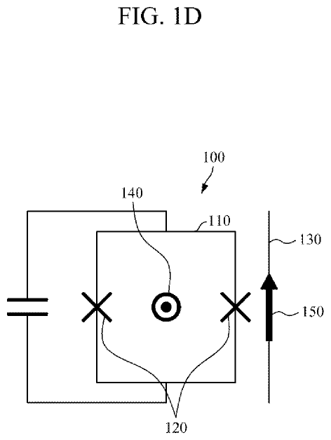

FIG. 1A illustrates a quantum computer chip, according to one or more embodiments. FIG. 1B is a circuit diagram of a frequency-fixed device, for example, a fixed qubit or a fixed qubit coupler, and FIG. 1C is a circuit diagram of a frequency-tunable device, for example, a tunable qubit or a tunable qubit coupler.

Referring to FIG. 1A, inside a quantum computer chip 10, there are multiple qubits 11 along with qubit couplers 15 connecting the qubits to each other. The qubit couplers 15 perform quantum entanglement and other interactions between the qubits. In the quantum computer chip 10, there are two or more qubits 11 present, and qubit couplers 15 facilitate interactions between these qubits.

The qubits 11 may be either of two classes of qubits, namely, fixed qubits with a fixed resonant frequency, or tunable qubits with a tunable (changeable) resonant frequency. Similarly, the qubit couplers 15 may be either couplers with a fixed resonant frequency or tunable qubit couplers with an adjustable resonant frequency.

A fixed qubit or a fixed qubit coupler may be formed, for example, with one capacitor 20 and one Josephson junction 25 (see FIG. 1B). On the other hand, a tunable qubit or a tunable qubit coupler may be formed, for example, with one capacitor 30 and two Josephson junctions 35 (see FIG. 1C).

In other words, qubits and couplers may have the same general structure, and they may be selected and used as either qubits or couplers depending on the purpose.

Furthermore, tunable qubits may be tuned to set a desired resonant frequency, and the resonant frequency of tunable qubit couplers may be tuned between two different frequencies to control their turning on and off of quantum entanglement of the qubits that they couple.

In the following description related to a tunable qubit, a desired resonant frequency may be set by applying voltage to a structure containing a ferromagnetic material.

FIG. 1D is a circuit diagram for describing resonant frequency control of a tunable qubit, according to one or more embodiments.

Referring to FIG. 1D, a tunable qubit 100 includes a superconducting quantum interface device (SQUID) 110 including two Josephson junctions 120, and requires a separate control line 130 adjacent to the qubit to apply a local magnetic field to the qubit.

Upon application of a control current 150 to the control line 130, a magnetic field is formed around the control line 130, and the formed magnetic field changes a magnetic flux 140 of the magnetic field passing through the SQUID. The change in the magnetic flux of the magnetic field passing through the SQUID causes a change in the critical current of either or both of the Josephson junctions 120. The resonant frequency of the tunable qubit 100 may be adjusted by adjusting the control current 150 applied to the control line 130, since the tunable qubit's 100 resonant frequency is determined by the critical current of the Josephson junctions 120.

However, the tunable qubit 100 has drawbacks in that, during its operation, tuning the tunable qubit 100 to have a desired resonant frequency requires constant application of a relatively high control current of several milliamperes (mA), which may lead to issues such as heat generation due to the control current and crosstalk with other devices. Also, a separate cryogenic electronic device is required for applying direct current (DC) control current through the control line.

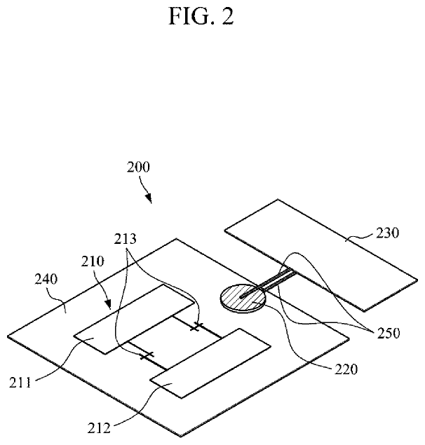

FIG. 2 illustrates a superconducting device including a tunable qubit, according one or more embodiments.

A tunable qubit 210, which is a qubit whose resonant frequency is tunable, may include a first conductive pad 211 and a second conductive pad 212 that are positioned on a substrate 240 and connected to each other via two Josephson junctions 213.

The Josephson effect is a phenomenon of current flowing through a thin insulator when placed between, for example, two superconducting materials. Each Josephson junction 213 may be characterized by a weak link between two superconducting materials bonded with an insulator. In this case, various types of metals may be used, in addition to insulators, as materials for the weak link that forms the Josephson junction 213.

The first conductive pad 211 and the second conductive pad 212 may be formed of a superconducting material. In this case, both the first conductive pad 211 and the second conductive pad 212 may be formed from the same superconducting material or different superconducting materials. The superconducting material may be/include, as non-limiting examples, aluminum (Al), niobium (Nb), indium (In), alpha-tantalum (α-Ta), titanium (Ti), lead (Pb), vanadium (V), or compounds thereof (e.g., NbN, NbTiN, TiN, or VN). Although the term “superconducting material” (and similar) is used herein, the “superconducting” does not imply that the relevant material is presently superconducting. Rather, as used herein, “superconducting” refers to being capable of superconducting under conditions practical for quantum computing applications.

For the pads to be superconductive, they should satisfy a thickness specification. As non-limiting examples, the first conductive pad 211 and the second conductive pad 212 may be formed with a thickness ranging from 50 nanometers (nm) to 400 nanometers (nm) The structure 220 may be positioned at a predetermined distance from the tunable qubit 210. The structure 220 may include a ferromagnetic material.

A ferromagnetic material is one in which the magnetic moments or magnetizations of its atoms or molecules are generally aligned in a specific direction, even in the absence of an external magnetic field.

These magnetizations within a ferromagnetic material usually have a preferred specific alignment direction, and this property is referred to as magnetic anisotropy. Perpendicular magnetic anisotropy is where the magnetization of the ferromagnetic material prefers alignment in the perpendicular direction (e.g., +Z or −Z axis direction). In-plane magnetic anisotropy is where the magnetization prefers alignment in the horizontal direction (e.g., X-Y plane direction). The ferromagnetic material within the structure 220 may exhibit perpendicular magnetic anisotropy (its plane being parallel to the substrate 240). That is, the atoms/molecules of the ferromagnetic material of the structure 220 may have a bias towards magnetically aligning in a direction normal to the structure 220.

Generally, ferromagnetic materials may be formed using transition metals, such as iron (Fe), cobalt (Co), and nickel (Ni), metal compounds containing rare earth atoms such as neodymium (Nd) and samarium (Sm), or heterojunction structures of heavy metals, ferromagnetic materials, and oxide layers (e.g., Pt/Co/MgO, Pt/Co/AlOx, Pt/CoFeB/MgO, Pt/(Co/Ni)n, and Pt/(Co/Pt)n). The ferromagnetic material within the structure 220 may be gadolinium cobalt (GdCo), but is not limited to thereto.

The structure 220 may be positioned on the outer side of either of the two Josephson junctions. That is, the structure 220 may be placed at either end of the first and second conductive pads 211, 212.

Referring to FIG. 2, the structure 220 may be positioned on the outer side of the right Josephson junction 213 adjacent to a control circuit 230. The first conductive pad 211, the second conductive pad 212, and the Josephson junction 213 may be spaced apart from each other at a distance of, for example, tens of nanometers (nm) to several micrometers (μm), or any distance that allows for sufficient changing of the magnetic flux of the tunable qubit 210.

The structure 220 may further include an insulator and a heavy metal.

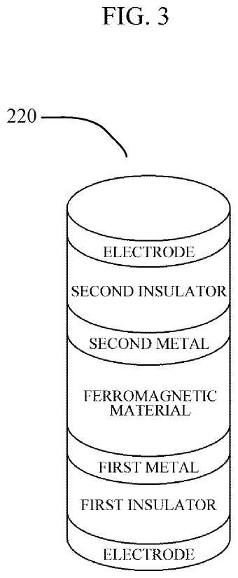

FIG. 3 illustrates an example of the structure 220, according to one or more embodiments.

Referring to FIG. 3, the structure 200 may include layers, in order from top to bottom of: a first electrode (e.g., Au), a first insulator, a first metal, a ferromagnetic material, a second metal, a second insulator, and a second electrode (e.g., Au). The first insulator and the second insulator may be formed of the same type of material (but not by necessity). Similarly, the first metal and the second metal may be formed of the same or the same type of material (but not by necessity). The ferromagnetic material, insulators, and metals included in the structure 220 are not limited, and various metals may be arranged. Any variation consistent with the functional purpose of the structure 220 may be used.

When implemented as a round structure, the diameter of the structure 220 may range from tens of nanometers to several micrometers (e.g., 90 μm), however, there is no restriction on the shape of the structure 220, which may include a squat cylindrical shape (the example shown in FIG. 3 is not an accurate representation of dimensional proportions) as well as a cuboid, a rectangle, or the like.

Referring back to FIG. 2, the control circuit 230 may apply voltage to a voltage control line 250 connected to the structure 220 to change the saturation magnetization of the ferromagnetic material (according to the application of the voltage), which in turn controls the resonant frequency of the tunable qubit. The control circuit 230 may change the saturation magnetization to control the resonant frequency by implementing a model that defines the relationship between (i) the saturation magnetization and (ii) a magnetic flux passing through the tunable qubit. The control circuit 230 may also implementing a model that defines the relationship between (i) the magnetic flux and (ii) the resonant frequency. As described next, the control circuit 230 may implement control of the qubit 210 by applying voltage to the structure 220 in a way that is consistent with these relationships:
structure saturation magnetization→qubit magnetic flux→qubit resonant frequency.

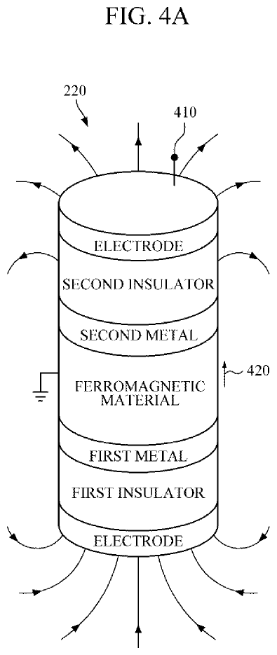

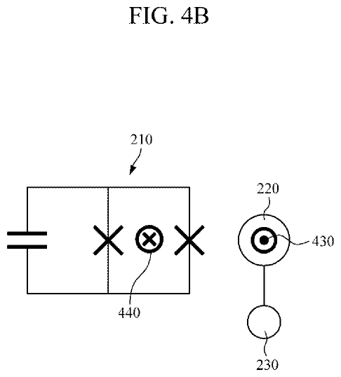

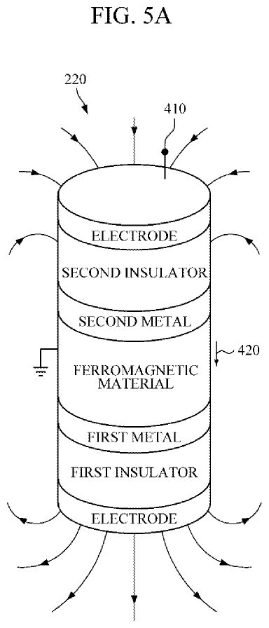

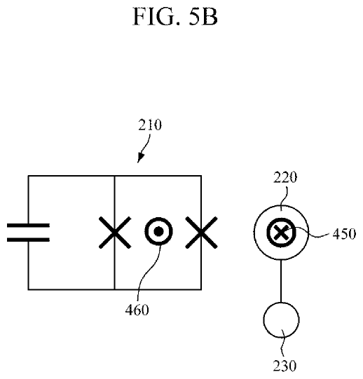

FIGS. 4A to 5B are circuit diagrams illustrating magnetic field radiation and the change in a magnetic flux of a magnetic field passing through a tunable qubit according to the application of voltage.

The ferromagnetic material having perpendicular magnetic anisotropy in the structure 220 may have its magnetization aligned in a direction perpendicular to the ground, for example, in a vertical upward direction (⊚) or in a vertical downward direction (⊗).

While the magnetic anisotropy of the structure 220 is described as “perpendicular”, it will be appreciated that the anisotropy direction of the structure 220 may be any direction that enables sufficient influence on qubit magnetic flux and therefore qubit resonant frequency. The anisotropy direction of the structure 220 may also be characterized as being in a direction that allows a magnetic field that it produces (including as induced by a voltage applied thereto) to sufficiently influence the magnetic flux of the qubit. It so happens that an anisotropic direction that is perpendicular to a plane of the qubit is convenient to this purpose, however, other anisotropic directions may also suffice, depending on other characteristics of the overall qubit (e.g., arrangement of the structure 220 relative to the qubit). In some embodiments, the “perpendicular” anisotropic direction refers to a direction that is perpendicular to a plane defined by (or parallel to) the qubit, e.g., a plane of its substrate, a plane of a “circuit board” containing the qubit, a plane parallel to the “flatness” plane of the qubit, a plane defined by the relative arrangement of the components of the qubit relative to each other (e.g., a plane roughly containing the conductive pads, or the Josephson junctions, or both). This foregoing also applies to the term “vertical”, where it refers to current or magnetization-bias direction.

When the control circuit 230 applies voltage in a vertical direction to the structure 220 through the voltage control line 250, the saturation magnetization of the ferromagnetic material may vary.

When a ferromagnetic material is magnetized, e.g., by a magnetic field applied thereto, the magnetic flux density (of the magnetic field generated by the magnetization of the ferromagnetic material) increases with the intensity of the applied magnetic field. However, that generated magnetic flux density reaches a maximum density after which it does not become stronger no matter how much the intensity of the applied magnetic field is increased beyond that point. When the magnetization of the ferromagnetic material reaches this limit is referred to as its saturation magnetization. In short, the saturation magnetization is a kind of maximum magnetization level.

Usefully, the saturation magnetization of the ferromagnetic material may vary depending on the intensity of the voltage applied to the ferromagnetic material. For instance, increasing the applied voltage may increase the saturation magnetization, while decreasing the applied voltage may lower the saturation magnetization.

In addition, the saturation magnetization may change based on the polarity of the voltage applied to the ferromagnetic material. For example, applying positive voltage may increase the saturation magnetization, and applying negative voltage may decrease the saturation magnetization.

In this case, opposite results may be obtained depending on the type of the ferromagnetic material. For example, for another ferromagnetic material, increasing the applied voltage may decrease the saturation magnetization, while decreasing the applied voltage may increase it. Additionally, applying positive voltage may decrease the saturation magnetization, while applying negative voltage may increase it.

Referring to FIGS. 4A and 4B, according to an embodiment, when the control circuit 230 connected to the voltage control line 250 applies negative voltage (V_{G}<0, where V_{G} is gate voltage) in a vertical direction to the structure 220 through a terminal 410, the saturation magnetization in the ferromagnetic material may undergo a change. As a result, net magnetization (Mnet) 420 may be generated in the vertical upward direction (⊚) 430, allowing the magnetic field to extend in the vertical upward direction (⊚) 430. At this point, the extending magnetic field (e.g., stray field) moves as if radiating from the N-pole of a permanent magnet, and may induce a magnetic flux (⊗) 440 in the vertical downward direction (⊗) on the nearby tunable qubit 210. In this case, increasing the voltage intensity in the negative direction may lead to an increase in saturation magnetization. Consequently, the net magnetization 420 increases and the strength of the magnetic field extending in the vertical upward direction 430 may increase. As a result, the intensity (density) of the magnetic flux (⊗) 440 of the tunable qubit 210 may also increase.

Referring to FIGS. 5A and 5B, according to an embodiment, when the control circuit 230 connected to the voltage control line 250 applies positive voltage (V_{G}>0, where V_{G} is gate voltage) in a vertical direction to the structure 220 through the terminal 410, the saturation magnetization in the ferromagnetic material may undergo a change. As a result, net magnetization (Mnet) 420 may be generated in the vertical downward direction (⊗) 450, allowing the magnetic field to extend in the vertical upward direction (⊗) 450. At this point, the extending magnetic field (e.g., stray field) moves as if radiating from the N-pole of a permanent magnet, and may induce a magnetic flux (⊚) 460 in the vertical upward direction on the nearby tunable qubit 210. In this case, increasing the voltage intensity in the positive direction may lead to an increase in saturation magnetization. Consequently, the net magnetization 420 increases and the strength of the magnetic field extending in the vertical downward direction (⊗) 450 may increase. As a result, the intensity (density) of the magnetic flux 460 of the tunable qubit 210 may also increase.

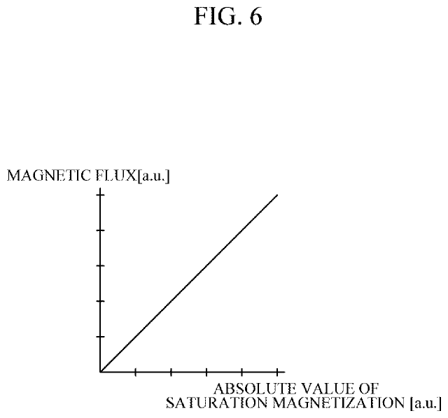

As illustrated in FIGS. 4A to 5B, a model defining the relationship between the saturation magnetization of the ferromagnetic material and the magnetic flux passing through the tunable qubit may be created, which may be expressed by the graph shown in FIG. 6.

FIG. 6 shows a relationship between the saturation magnetization of a ferromagnetic material and the magnetic flux passing through a tunable qubit, according to one or more embodiments. Referring to FIG. 6, it can be seen that the magnetic flux passing through the tunable qubit is proportional to the absolute value of the saturation magnetization of the ferromagnetic material. For example, increasing the intensity of the applied voltage in the positive or negative direction may result in an increase in the saturation magnetization in the ferromagnetic material. This leads to an increase in the strength of the stray field of the ferromagnetic material, ultimately causing an increase in the intensity of the magnetic flux passing through the tunable qubit.

When the magnetic flux is obtained according to the model by adjusting the saturation magnetization of the ferromagnetic material through the application of voltage by the control circuit 230, the resonant frequency of the tunable qubit may be ultimately acquired based on a predefined model that defines the relationship between the magnetic flux and the resonant frequency.

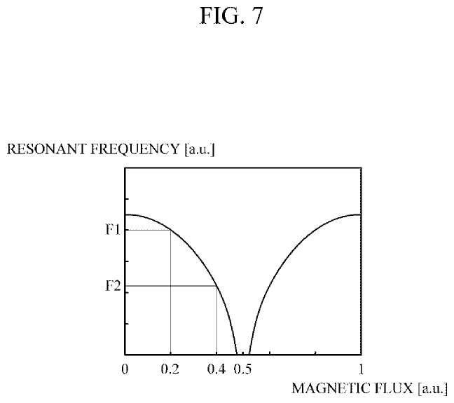

FIG. 7 shows a relationship between magnetic flux and resonant frequency, according to one or more embodiments.

Referring to FIG. 7, for example, when the magnetic flux 440 obtained according to FIGS. 4A and 4B is 0.2, the resonant frequency may correspond to F1, and the magnetic flux 460 obtained according to FIGS. 5A and 5B is 0.4, the resonant frequency may correspond to F2.

For a conventional tunable qubit (see, e.g., FIG. 1D), to maintain a desired resonant frequency, the tunable qubit is driven by a volatile control method in which a relatively high control current of several milliamperes is continuously applied during the operation of the qubit. This method is inefficient and causes heat generation due to control current, noise (e.g., 1/f noise), and crosstalk with other devices, potentially reducing the reliability of the measured resonant frequency. Additionally, a separate cryogenic electronic device may be required for supplying the control current.

When the resonant frequency of a tunable qubit is controlled by applying voltage to change the saturation magnetization of the ferromagnetic material, there is no need for a control line for applying a control current that is generally required for a conventional tunable qubit. This may reduce heat generation due to the control current, noise, and crosstalk, potentially enabling relatively stable resonance frequency control.

In one or more embodiments, the tunable qubit 210 may be of a gatemon type. A gatemon-type qubit allows the adjustment of Josephson energy by applying gate voltage to the insulator of the Josephson junction. The resonant frequency of the tunable qubit 210 may be efficiently adjusted by applying gate voltage to the insulator of the Josephson junction, in addition to applying voltage to the ferromagnetic material structure 220 by the control circuit 230.

According to one or more embodiments, the tunable qubit 210 may be of a transmon type. A transmon-type qubit is designed to have a higher ratio of Josephson energy to charge energy to reduce sensitivity to charge noise. A Josephson junction may be formed by placing an insulator between two shunt capacitors corresponding to the first and second conductive pads that are made of a superconducting material.

As described above, the tunable qubit and the tunable qubit coupler, which are frequency-tunable devices, may have the same structure, and thus, depending on the intended use, they may be selected as either the qubit or the coupler. Therefore, the above embodiments may be employed as a tunable qubit coupler as well as a tunable qubit.

For example, by applying voltage to a structure containing a ferromagnetic material near the tunable qubit coupler, the resonant frequency of the coupler may be controlled into two stages: on/off.

In FIG. 2, the superconducting device including the tunable qubit is illustrated as existing in a single layer. However, it and other tunable qubits described herein may also exist in the form of multiple layers stacked together. For example, the structure and the tunable qubit may be formed in a stacked structure from bottom to top.

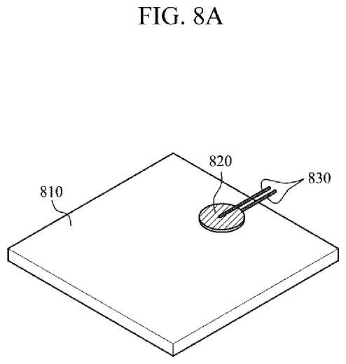

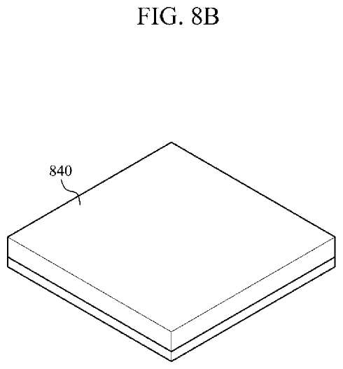

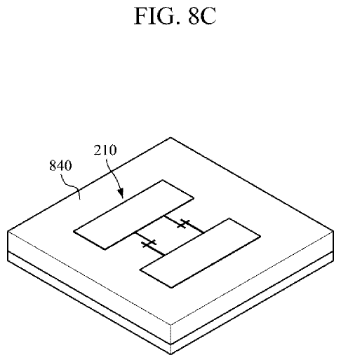

FIGS. 8A to 8C illustrate a process of manufacturing a superconducting device, according to one or more embodiments.

Referring to FIGS. 8A to 8C, initially, a structure 820 and a voltage control line 830 connected to a control circuit may be arranged on a substrate 810 (see FIG. 8A). Then, an insulating layer 840 made of an insulating material may be arranged (see FIG. 8B) atop the substrate 810 and structure 820, and finally, a tunable qubit 210 may be arranged (see FIG. 8C).

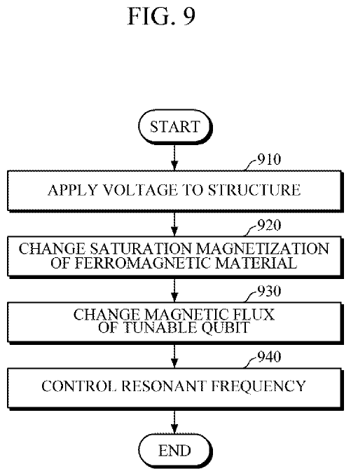

FIG. 9 illustrates a method for controlling a resonant frequency of a tunable qubit, according to one or more embodiments.

FIG. 9 illustrates a method of controlling the resonant frequency of any of the tunable qubits described with reference to FIGS. 2 to 8C. To avoid redundancy, only a brief description is provided.

The superconducting device may include a tunable qubit including first and second conductive pads connected by a Josephson junction, and a structure containing a ferromagnetic material (a ferromagnetic structure or a ferromagnetic circuit element). The tunable qubit may include two Josephson junctions, and the structure may be positioned on the outer side of either of the two Josephson junctions.

The superconducting device may first apply voltage to the structure in 910. The superconducting device may apply the voltage in a direction vertical to the structure (or, a direction between two electrodes of the structure). The structure may further include an insulator and a heavy metal, and the ferromagnetic material may be gadolinium cobalt (GdCo), as a non-limiting example.

Then, the superconducting device may change the saturation magnetization of the ferromagnetic material in 920. When the ferromagnetic material is magnetized, the magnetic flux density increases with the intensity of a magnetic field. However, once the magnetic flux density reaches a certain value, it does not become stronger no matter how much the intensity of the magnetic field is increased beyond that point, and the magnetization that reaches this limit is referred to as saturation magnetization. The saturation magnetization may be varied by changing the intensity and/or polarity of the applied voltage.

Then, the superconducting device may change the intensity/density of magnetic flux of the magnetic field passing through the tunable qubit in 930, and as a result, control the resonant frequency in 940. For example, a superconducting qubit-based device may control the resonant frequency using a model that defines the relationship between the saturation magnetization and a magnetic flux, as well as a model that defines the relationship between the magnetic flux and the resonant frequency.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A superconducting device comprising:
a frequency-tunable device comprising a Josephson junction, a first conductive pad and a second conductive pad connected with the first conductive pad by the Josephson junction;
a structure comprising a ferromagnetic material; and
a control circuit configured to control a resonant frequency of the frequency-tunable device by applying voltage to the structure to change the saturation magnetization of the ferromagnetic material.

2. The superconducting device of claim 1, wherein the frequency-tunable device comprises a tunable qubit or a tunable qubit coupler.

3. The superconducting device of claim 2, wherein the structure is configured so that the voltage flows through the structure in a direction perpendicular to a plane of the superconducting device.

4. The superconducting device of claim 3, wherein the control circuit is configured to change the saturation magnetization to control the resonant frequency according to a relationship between the saturation magnetization and a magnetic flux passing through the frequency-tunable device, and according to a relationship between the magnetic flux and the resonant frequency.

5. The superconducting device of claim 1, wherein the structure further comprises an insulator and a heavy metal.

6. The superconducting device of claim 2, wherein the frequency-tunable device comprises the tunable qubit, the tunable qubit comprises two Josephson junctions, and one of the Josephson junctions is between the other Josephson junction and the structure.

7. The superconducting device of claim 1, wherein the structure has a flat shape and the ferromagnetic material has a direction of magnetic anisotropy that is perpendicular to flat shape.

8. The superconducting device of claim 1, wherein the ferromagnetic material comprises gadolinium cobalt (GdCo).

9. The superconducting device of claim 1, wherein the structure has a width that is less than 90 micrometers (μm).

10. The superconducting device of claim 1, wherein the first conductive pad and the second conductive pad are formed of a superconducting material.

11. The superconducting device of claim 10, wherein the superconducting material includes aluminum (Al), niobium (Nb), indium (In), alpha-tantalum (α-Ta), titanium (Ti), lead (Pb), vanadium (V), or compounds thereof.

12. The superconducting device of claim 1, wherein the frequency-tunable device is of a gatemon type.

13. The superconducting device of claim 1, wherein the structure and the frequency-tunable device are formed in a stacked structure from bottom to top.

14. A method of controlling a resonant frequency of a frequency-tunable device through a superconducting device, the superconducting device comprising the frequency-tunable device, the frequency-tunable device comprising a first conductive pad, a second conductive pad, a Josephson junction connecting the first conductive pad to the second conductive pad, and a structure which includes a ferromagnetic material, the method comprising:
applying voltage to the structure;
the application of the voltage causing a change to the saturation magnetization of the ferromagnetic material, the ferromagnetic material providing a magnetic field;
the change of the saturation magnetization of the ferromagnetic material changing a magnetic flux of the magnetic field where it passes through the frequency-tunable device; and
the changing of the magnetic flux changing the resonant frequency of the frequency-tunable device.

15. The method of claim 14, wherein the frequency-tunable device comprises a tunable qubit or a tunable qubit coupler.

16. The method of claim 14, wherein the voltage moves through the structure in a direction perpendicular to a planar dimension of the structure.

17. The method of claim 14, wherein the resonant frequency is changed according to a relationship between the saturation magnetization and the magnetic flux and according to a relationship between the magnetic flux and the resonant frequency.

18. The method of claim 14, wherein the structure further comprises an insulator and a heavy metal, the frequency-tunable device comprises two Josephson junctions, and the structure is positioned outside of a space between the two Josephson junctions.

19. The method of claim 14, wherein the frequency-tunable device is of a transmon type.

20. A method of changing a resonant frequency of a superconducting quantum interface device (SQUID) device comprising a Josephson junction and a ferromagnetic structure arranged near the SQUID device, the method comprising:
emitting, from the ferromagnetic structure, a magnetic field that passes through an area of the SQUID; and
changing the resonant frequency of the SQUID device by applying a voltage to the superconductive ferromagnetic structure to change the saturation magnetization of the ferromagnetic structure to change the magnetic flux of the magnetic field passing through the area of the SQUID device.
